(19) United States
(12) Patent Application Publication
(10) Pub. No.: US 2025/0372419 A1
(43) Pub. Date: Dec. 4, 2025

(54) SUBSTRATE LIQUID PROCESSING APPARATUS, SUBSTRATE LIQUID PROCESSING METHOD, AND IMAGE PROCESSING METHOD

(71) Applicant: Tokyo Electron Limited, Tokyo (JP)

(72) Inventors: Sangwon PARK, Kikuchi-gun, Kumamoto (JP); Kazuya HISANO, Koshi City, Kumamoto (JP)

(21) Appl. No.: 19/219,314

(22) Filed: May 27, 2025

(30) Foreign Application Priority Data
Jun. 3, 2024 (JP) 2024-090117

(51) Int. Cl. H01L 21/67; G06T 5/73; G06T 7/00; G06T 7/73

(52) U.S. Cl. CPC H01L 21/67259; G06T 5/73; G06T 7/001; G06T 7/74; H01L 21/67086; G06T 2207/20192; G06T 2207/30148

(57) ABSTRACT

A substrate liquid processing apparatus includes a processing tank storing a processing liquid, a substrate support supporting substrates in an upright posture with an interval, a support mover moving the substrate support to arrange the substrates at a processing position where the substrates are positioned within the processing tank to be immersed in the processing liquid and at a retreat position where the substrates are positioned outside the processing tank, an image capturer acquiring a captured image of outer peripheral end faces of the substrates, and an image processor making a determination on a positional misalignment between the substrates before immersion and the substrates after immersion, based on a comparison between the captured image before immersion and the captured image after immersion.

### CROSS-REFERENCE TO RELATED APPLICATION

This application is based upon and claims the benefit of priority from Japanese Patent Application No. 2024-090117, filed on Jun. 3, 2024, the entire contents of which are incorporated herein by reference.

### TECHNICAL FIELD

The present disclosure relates to a substrate liquid processing apparatus, a substrate liquid processing method, and an image processing method.

### BACKGROUND

Patent Document 1 discloses a technique for checking that a substrate is properly held by a substrate support member while being immersed in a processing liquid.

### PRIOR ART DOCUMENTS

### Patent Documents

Patent Document 1: Japanese laid-open publication No. 2022-158331

### SUMMARY

According to one embodiment of the present disclosure, there is provided a substrate liquid processing apparatus including a processing tank configured to store a processing liquid; a substrate support member configured to support a plurality of substrates in an upright posture with an interval therebetween; a support mover configured to move the substrate support member, so as to arrange the plurality of substrates at a processing position where the plurality of substrates are positioned within the processing tank so as to be immersed in the processing liquid and at a retreat position where the plurality of substrates are positioned outside the processing tank; an image capturer configured to acquire a captured image of outer peripheral end faces of the plurality of substrates; and an image processor configured to make a determination depending on a positional misalignment between the plurality of substrates before immersion in the processing liquid and the plurality of substrates after immersion in the processing liquid, based on a comparison between the captured image of the outer peripheral end faces of the plurality of substrates before immersion in the processing liquid and the captured image of the outer peripheral end faces of the plurality of substrates after immersion in the processing liquid.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view illustrating an example of the overall configuration of a substrate liquid processing system.

FIG. 2 is a system diagram illustrating an example of the configuration of an etching processing apparatus incorporated in the substrate liquid processing system.

FIG. 3 is a schematic transverse vertical cross-sectional view illustrating an example of a processing tank of the etching processing apparatus.

FIG. 4 is a schematic longitudinal vertical cross-sectional view of the processing tank.

FIG. 5 is a schematic plan view illustrating an example of the processing tank.

FIG. 6 is a transverse vertical cross-sectional view of an example of the processing tank illustrating in detail only lids at a closed position and surrounding members thereof.

FIG. 7 is a perspective view of an example of the lids.

FIG. 8 is a transverse vertical cross-sectional view illustrating the lid at an open position after being moved from the closed position illustrated in FIG. 6.

FIG. 9 is a schematic diagram illustrating an example of a camera (image capturer) and an illuminator, which are arranged near the processing tank.

FIG. 10 is a diagram illustrating an example of a captured image of the outer peripheral end face of a substrate.

FIG. 11 is a flowchart illustrating an example of a substrate liquid processing method.

FIG. 12 is a flowchart illustrating an example of an image processing method.

FIG. 13A is a diagram illustrating an example of a partial region of a captured image and is a conceptual diagram illustrating the image processing method illustrated in FIG. 12.

FIG. 13B is a diagram illustrating an example of a partial region of a captured image and is a conceptual diagram illustrating the image processing method illustrated in FIG. 12.

FIG. 13C is a diagram illustrating an example of a partial region of a captured image and is a conceptual diagram illustrating the image processing method illustrated in FIG. 12.

FIG. 13D is a diagram illustrating an example of a partial region of a captured image and is a conceptual diagram illustrating the image processing method illustrated in FIG. 12.

FIG. 13E is a diagram illustrating an example of a partial region of a captured image and is a conceptual diagram illustrating the image processing method illustrated in FIG. 12.

FIG. 13F is a diagram illustrating an example of a partial region of a captured image and is a conceptual diagram illustrating the image processing method illustrated in FIG. 12.

FIG. 13G is a diagram illustrating an example of a partial region of a captured image and is a conceptual diagram illustrating the image processing method illustrated in FIG. 12.

FIG. 14 is a diagram illustrating an example of a comparison between a captured image before liquid processing and a captured image after liquid processing.

FIG. 15 is a partially enlarged plan view schematically illustrating an example of the outer peripheral end face of a substrate.

FIG. 16 is a flowchart illustrating an example of an edge enhancement processing method (substrate end face enhancement processing method) executed by an image processor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings.

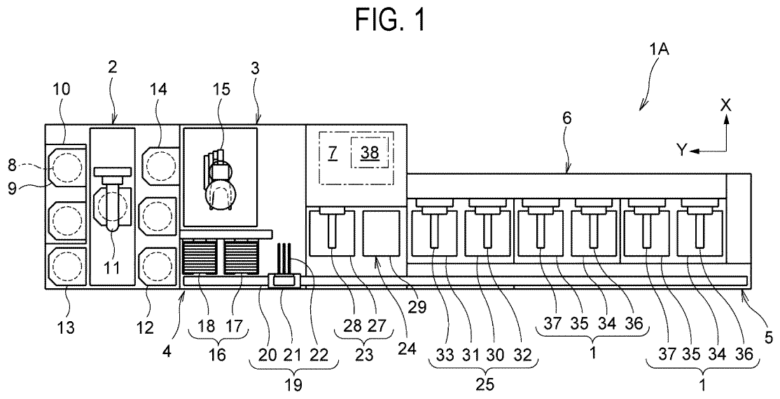

FIG. 1 is a schematic plan view illustrating an example of the overall configuration of a substrate liquid processing system 1A.

The substrate liquid processing system 1A illustrated in FIG. 1 includes a carrier loading/unloading section 2, a lot formation section 3, a lot placement section 4, a lot transfer section 5, a lot processing section 6, and a controller 7.

The carrier loading/unloading section 2 performs loading and unloading of a carrier 9, which accommodates a plurality of (e.g., 25) substrates (e.g., silicon wafers) 8 arranged vertically in a horizontal posture. Each substrate 8 has a disk shape and includes a notch (cutout) on the outer periphery thereof.

The carrier loading/unloading section 2 is provided with a carrier stage 10 capable of placing a plurality of carriers 9 thereon, a carrier transfer mechanism 11 for performing transfer of the carriers 9, carrier stocks 12 and 13 for temporarily storing the carriers 9, and a carrier placement table 14 capable of placing the carrier 9 thereon. The carrier stock 12 temporarily stores the substrates 8, which will become products, before they are processed in the lot processing section 6. The carrier stock 13 temporarily stores the substrates 8 which will become products after they have been processed in the lot processing section 6.

The carrier loading/unloading section 2 transfers the carrier 9, which has been loaded onto the carrier stage 10 from the outside, to the carrier stock 12 or the carrier placement table 14 using the carrier transfer mechanism 11. Further, the carrier loading/unloading section 2 transfers the carrier 9 placed on the carrier placement table 14 to the carrier stock 13 or the carrier stage 10 using the carrier transfer mechanism 11. The carrier 9 transferred to the carrier stage 10 is then unloaded to the outside.

The lot formation section 3 combines the substrates 8 accommodated in one or more carriers 9 to form a lot (also referred to as “processing lot” or “batch”) that is composed of a plurality of substrates 8 (e.g., 50 to 100 substrates) to be simultaneously processed. The lot may include two substrates 8 adjacent to each other, with respective patterned surfaces thereof facing each other. Alternatively, the patterned surfaces of all of the substrates 8 included in the lot may be oriented in the same direction.

The lot formation section 3 is provided with a substrate transfer mechanism 15 for transferring the plurality of substrates 8. The substrate transfer mechanism 15 may change the posture of the substrates 8 from a horizontal posture to a vertical posture and from a vertical posture to a horizontal posture during the transfer of the substrates 8.

The lot formation section 3 transfers the substrates 8 from the carrier 9 placed on the carrier placement table 14 to the lot placement section 4 using the substrate transfer mechanism 15 to place the substrates 8, which form the lot, on the lot placement section 4. The lot formation section 3 also transfers the lot placed on the lot placement section 4 to the carrier 9 placed on the carrier placement table 14 using the substrate transfer mechanism 15. The substrate transfer mechanism 15 includes, as a substrate support for supporting the plurality of substrates 8, an unprocessed substrate support for supporting unprocessed substrates 8 before transfer by the lot transfer section 5, and a processed substrate support for supporting processed substrates 8 after transfer by the lot transfer section 5. The substrate support having such a configuration prevents particles and other contaminants adhering to the unprocessed substrates 8 and others from moving and adhering to the processed substrates 8.

The lot placement section 4 temporarily places (holds in standby) the lot, transferred between the lot formation section 3 and the lot processing section 6 by the lot transfer section 5, on a lot placement table 16.

The lot placement section 4 is provided with a loading-side lot placement table 17 for placing the lot before processing (before being transferred by the lot transfer section 5) and an unloading-side lot placement table 18 for placing the lot after processing (after being transferred by the lot transfer section 5). The plurality of substrates 8 corresponding to one lot are placed in a vertical posture and arranged in the front-rear direction on the loading-side and unloading-side lot placement tables 17 and 18.

In the lot placement section 4, the lot formed by the lot formation section 3 is placed on the loading-side lot placement table 17 and is then loaded into the lot processing section 6 via the lot transfer section 5. Further, in the lot placement section 4, the lot, which has been unloaded from the lot processing section 6, is transferred to and placed on the unloading-side lot placement table 18 via the lot transfer section 5 and is then transferred to the lot formation section 3.

The lot transfer section 5 performs transfer of the lot between the lot placement section 4 and the lot processing section 6 and within the interior of the lot processing section 6.

The lot transfer section 5 is provided with a lot transfer mechanism 19, which performs transfer of the lot. The lot transfer mechanism 19 includes a rail 20, which extends along the lot placement section 4 and the lot processing section 6, and a moving body 21, which moves along the rail 20 while holding the plurality of substrates 8. The moving body 21 is provided with a substrate holder 22, which is capable of holding the plurality of substrates 8 arranged in a vertical posture and in the front-rear direction. The substrate holder 22 is movable forward and backward.

The lot transfer section 5 receives the lot placed on the loading-side lot placement table 17 using the substrate holder 22 of the lot transfer mechanism 19, and delivers that lot to the lot processing section 6. The lot transfer section 5 also receives the lot processed in the lot processing section 6 using the substrate holder 22 of the lot transfer mechanism 19, and delivers the lot to the unloading-side lot placement table 18. Further, the lot transfer section 5 performs transfer of the lot within the interior of the lot processing section 6 using the lot transfer mechanism 19.

The lot processing section 6 performs processing such as etching, cleaning, and drying on each lot including the plurality of substrates 8 arranged in a vertical posture and in the front-rear direction.

In the lot processing section 6, a drying processing apparatus 23, a substrate holder cleaning processing apparatus 24, a cleaning processing apparatus 25, and an etching processing apparatus (substrate liquid processing apparatus) 1 are arranged side by side. The drying processing apparatus 23 performs drying processing on the substrates 8. The substrate holder cleaning processing apparatus 24 performs cleaning processing on the substrate holder 22. The cleaning processing apparatus 25 performs cleaning processing on the substrates 8. The etching processing apparatus (substrate liquid processing apparatus) 1 performs etching processing on the substrates 8.

The drying processing apparatus 23 includes a processing tank 27 and a substrate lifting mechanism 28, which is provided in a vertically movable manner within the processing tank 27. A drying gas (e.g., isopropyl alcohol (IPA)) is supplied to the processing tank 27. The substrate lifting mechanism 28 holds the plurality of substrates 8 corresponding to one lot arranged in a vertical posture and in the front-rear direction. The drying processing apparatus 23 receives the lot from the substrate holder 22 of the lot transfer mechanism 19 using the substrate lifting mechanism 28, and vertically moves that lot using the substrate lifting mechanism 28, thereby performing drying processing on the substrates 8 with the drying gas supplied to the processing tank 27. The drying processing apparatus 23 also delivers the lot from the substrate lifting mechanism 28 to the substrate holder 22 of the lot transfer mechanism 19.

The substrate holder cleaning processing apparatus 24 includes a processing tank 29 and is capable of supplying a cleaning processing liquid and a drying gas to the processing tank 29. As such, the substrate holder cleaning processing apparatus 24 performs cleaning processing on the substrate holder 22 by supplying the cleaning processing liquid and then the drying gas to the substrate holder 22 of the lot transfer mechanism 19.

The cleaning processing apparatus 25 includes a cleaning processing tank 30 and a rinsing processing tank 31, as well as substrate lifting mechanisms 32 and 33 provided in a vertically movable manner within the respective processing tanks 30 and 31. The cleaning processing tank 30 stores a cleaning processing liquid (e.g., SC-1). The rinsing processing tank 31 stores a rinsing processing liquid (e.g., pure water).

The etching processing apparatus 1 includes an etching processing tank 34 and a rinsing processing tank 35, as well as substrate lifting mechanisms 36 and 37 provided in a vertically movable manner within the respective processing tanks 34 and 35. The etching processing tank 34 stores an etching processing liquid (e.g., phosphoric acid aqueous solution). The rinsing processing tank 35 stores a rinsing processing liquid (e.g., pure water). As described above, the etching processing apparatus 1 configures a substrate liquid processing apparatus.

The cleaning processing apparatus 25 and the etching processing apparatus 1 have similar configurations. To describe the etching processing apparatus (substrate liquid processing apparatus) 1, the substrate lifting mechanism 36 holds the plurality of substrates 8 corresponding to one lot arranged in a vertical posture and in the front-rear direction. The etching processing apparatus 1 receives the lot from the substrate holder 22 of the lot transfer mechanism 19 using the substrate lifting mechanism 36 and vertically moves that lot using the substrate lifting mechanism 36, thereby performing etching processing on the substrates 8 by immersing the lot in the etching processing liquid within the processing tank 34. Thereafter, the etching processing apparatus 1 delivers the lot from the substrate lifting mechanism 36 to the substrate holder 22 of the lot transfer mechanism 19. Further, the etching processing apparatus 1 receives the lot from the substrate holder 22 of the lot transfer mechanism 19 using the substrate lifting mechanism 37 and vertically moves that lot using the substrate lifting mechanism 37, thereby performing rinsing processing on the substrates 8 by immersing the lot in the rising processing liquid within the processing tank 35. Thereafter, the etching processing apparatus 1 delivers the lot from the substrate lifting mechanism 37 to the substrate holder 22 of the lot transfer mechanism 19.

The controller 7 controls the operation of each section of the substrate liquid processing system 1A (e.g., each of the carrier loading/unloading section 2, the lot formation section 3, the lot placement section 4, the lot transfer section 5, the lot processing section 6, and the etching processing apparatus 1).

The controller 7 is configured, for example, by a computer and includes a computer-readable storage medium 38. The storage medium 38 stores programs for controlling a variety of processing executed in the substrate liquid processing apparatus 1. The controller 7 controls the operation of the substrate liquid processing apparatus 1 by reading and executing the programs stored in the storage medium 38. In addition, these programs may originally be stored in the computer readable storage medium 38, and may be installed from another storage medium into the storage medium 38 of the controller 7. Examples of the computer readable storage medium 38 may include a hard disk (HD), a flexible disk (FD), a compact disk (CD), a magneto-optical disk (MO), and a memory card.

As described above, in the processing tank 34 of the etching processing apparatus 1, an aqueous solution (phosphoric acid aqueous solution) with a predetermined concentration of chemical agent (phosphoric acid) is used as a processing liquid (etching liquid) to perform liquid processing (etching processing) on the substrates 8.

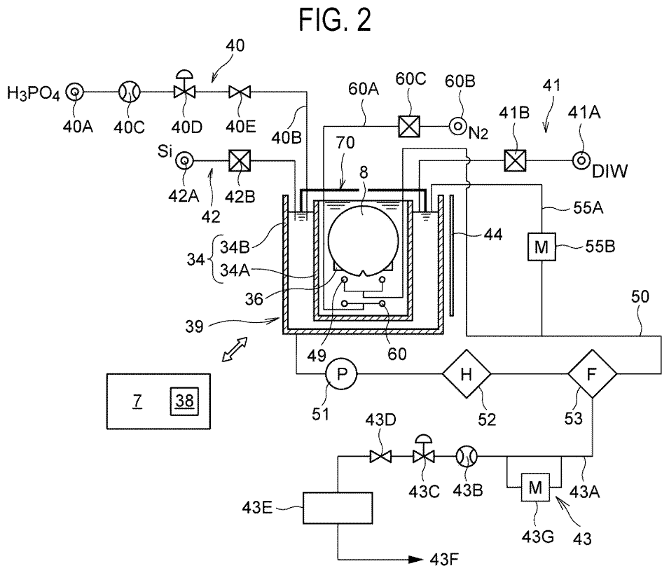

FIG. 2 is a system diagram illustrating an example of a configuration of the etching processing apparatus 1 incorporated in the substrate liquid processing system 1A.

The etching processing apparatus 1 includes the above-described processing tank 34, which stores, as a processing liquid, a phosphoric acid aqueous solution with a predetermined concentration. The processing tank 34 includes an inner tank 34A and an outer tank 34B. The phosphoric acid aqueous solution overflowing from the inner tank 34A is introduced into the outer tank 34B. The liquid level in the outer tank 34B is maintained lower than the liquid level in the inner tank 34A.

The upstream end of a circulation line 50 is connected to the bottom of the outer tank 34B. The downstream end of the circulation line 50 is connected to a processing liquid supply nozzle 49 installed within the inner tank 34A. A pump 51, a heater 52, and a filter 53 are interposed in sequence from the upstream side along the circulation line 50. When the pump 51 is driven, a circulation flow of the phosphoric acid aqueous solution is created, in which the solution is directed from the outer tank 34B into the inner tank 34A through the circulation line 50 and the processing liquid supply nozzle 49, and then is introduced back from the inner tank 34A into the outer tank 34B.

A liquid processor 39 is formed by the processing tank 34, the circulation line 50, and equipment provided in the circulation line 50 (e.g., a pump 51, a heater 52, and a filter 53). Further, the processing tank 34 and the circulation line 50 constitute a circulation system.

A gas nozzle 60 (for bubbling) is provided below the processing liquid supply nozzle 49 within the inner tank 34A to discharge bubbles of an inert gas, such as nitrogen gas, into the phosphoric acid aqueous solution within the inner tank 34A. The inert gas, such as nitrogen gas, is supplied to the gas nozzle 60 from a gas supply source 60B via a flow-rate regulator 60C, which is composed of an on-off valve, a flow-rate control valve, a flow meter, and others.

The processing tank 34 is provided with the above-described substrate lifting mechanism 36. The substrate lifting mechanism 36 can hold the plurality of substrates 8 in a vertically upright posture, which are arranged at intervals in the horizontal direction, and also move vertically while maintaining this arrangement.

The etching processing apparatus 1 includes a phosphoric acid aqueous solution supplier 40 for supplying the phosphoric acid aqueous solution to the liquid processor 39, a pure water supplier 41 for supplying pure water to the liquid processor 39, a silicon supplier 42 for supplying a silicon solution to the liquid processor 39, and a phosphoric acid aqueous solution discharger 43 for discharging the phosphoric acid aqueous solution from the liquid processor 39.

The phosphoric acid aqueous solution supplier 40 supplies a predetermined concentration of phosphoric acid aqueous solution to a certain part within the circulation system composed of the processing tank 34 and the circulation line 50, i.e., a part within the liquid processor 39. It is desirable to supply the phosphoric acid aqueous solution to the outer tank 34B as illustrated. The phosphoric acid aqueous solution supplier 40 includes a phosphoric acid aqueous solution supply source 40A, which is a tank storing the phosphoric acid aqueous solution, a phosphoric acid aqueous solution supply line 40B, which connects the phosphoric acid aqueous solution supply source 40A to the outer tank 34B, and a flow meter 40C, flow-rate control valve 40D, and on-off valve 40E interposed in sequence from the upstream side along the phosphoric acid aqueous solution supply line 40B. The phosphoric acid aqueous solution supplier 40 may supply the phosphoric acid aqueous solution to the outer tank 34B at a controlled flow rate via the flow meter 40C and the flow-rate control valve 40D.

The pure water supplier 41 supplies pure water to replenish water that evaporates due to heating of the phosphoric acid aqueous solution. The pure water supplier 41 includes a pure water supply source 41A for supplying pure water at a predetermined temperature, and the pure water supply source 41A is connected to the outer tank 34B via a flow-rate regulator 41B. The flow-rate regulator 41B may be composed of an on-off valve, a flow-rate control valve, a flow meter, and others.

The silicon supplier 42 includes a silicon supply source 42A, which is a tank storing a silicon-containing compound solution such as a solution in which colloidal silicon is dispersed, and a flow-rate regulator 42B. The flow-rate regulator 42B may be composed of an on-off valve, a flow-rate control valve, a flow meter, and others.

The phosphoric acid aqueous solution discharger 43 is provided to discharge the phosphoric acid aqueous solution within the circulation system composed of the liquid processor 39 and the circulation line 50, i.e., within the liquid processor 39. The phosphoric acid aqueous solution discharger 43 includes a discharge line 43A that branches off from the circulation line 50, and a flow meter 43B, flow-rate control valve 43C, and on-off valve 43D provided in sequence from the upstream side along the discharge line 43A, and a cooling tank 43E. The phosphoric acid aqueous solution discharger 43 may discharge the phosphoric acid aqueous solution at a controlled flow rate via the flow meter 43B and the flow-rate control valve 43C.

The cooling tank 43E temporarily stores and cools the phosphoric acid aqueous solution that has flowed through the discharge line 43A. The phosphoric acid aqueous solution (see reference numeral 43F) from the cooling tank 43E may be discarded to a factory waste liquid system (not illustrated). Alternatively, after removing silicon contained in the phosphoric acid aqueous solution using a regeneration device (not illustrated), the phosphoric acid aqueous solution may be returned to the phosphoric acid aqueous solution supply source 40A for reuse.

In the illustrated example, the discharge line 43A is connected to the circulation line 50 (at the position of a filter drain in the drawing) but is not limited thereto, and may also be connected to another part of the circulation system such as the bottom of the inner tank 34A.

The discharge line 43A is provided with a silicon concentration meter 43G for measuring the silicon concentration in the phosphoric acid aqueous solution. Further, a phosphoric acid concentration meter 55B for measuring the phosphoric acid concentration in the phosphoric acid aqueous solution is interposed in a branch line 55A that branches off from the circulation line 50 and is connected to the outer tank 34B. The outer tank 34B is provided with a liquid level meter 44 for detecting the liquid level within the outer tank 34B.

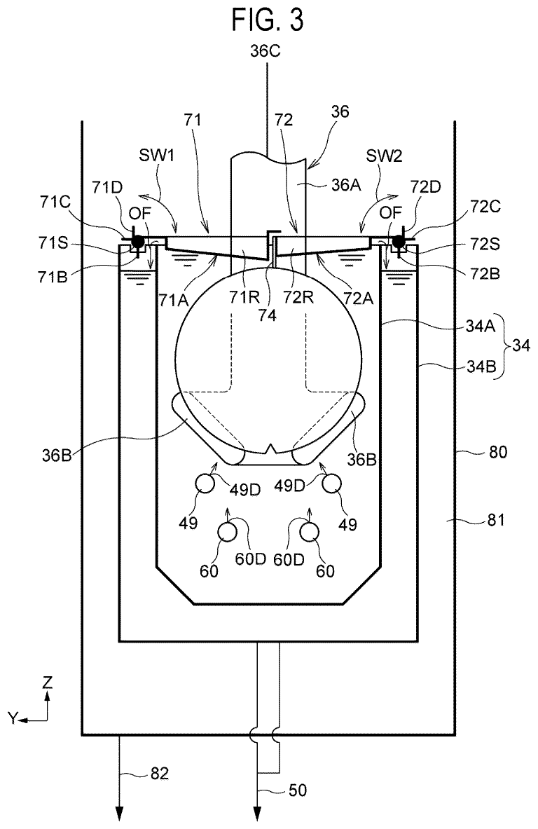

Next, the configuration of the processing tank 34 of the etching processing apparatus 1 will be described with reference to FIGS. 3 to 7. For the convenience of description, an XYZ orthogonal coordinate system is set and referenced as necessary. In addition, the negative X direction is referred to as the “front side” or “front”, the positive X direction is referred to as the “rear side” or “rear”, the negative Y direction is referred to as the “right side” or “right”, and the positive Y direction is referred to as the “left side” or “left”.

As described above, the processing tank 34 includes the inner tank 34A with an open top and the outer tank 34B with an open top. The inner tank 34A is accommodated in the interior of the outer tank 34B. The phosphoric acid aqueous solution overflowing from the inner tank 34A is introduced into the outer tank 34B. During liquid processing, most of the inner tank 34A, including the bottom, is immersed in the phosphoric acid aqueous solution within the outer tank 34B.

The outer tank 34B is accommodated in the interior of a liquid receiving container (sink) 80, and a drain space 81 is formed between the outer tank 34B and the liquid receiving container 80. A drain line 82 is connected to the bottom of the drain space 81.

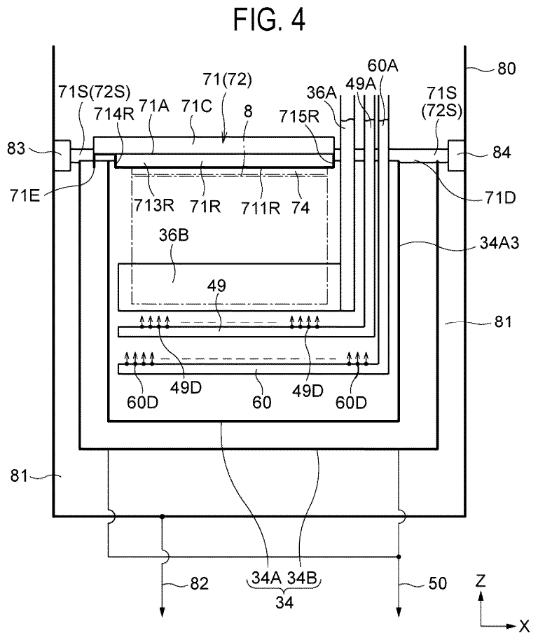

The processing liquid supply nozzle 49 is in a form of a cylindrical body extending in the X direction (horizontal direction) within the inner tank 34A. The processing liquid supply nozzle 49 discharges a processing liquid from a plurality of discharge holes 49D (see FIGS. 3 and 4) perforated in the peripheral surface thereof toward the substrates 8 held by the substrate lifting mechanism 36. Although two processing liquid supply nozzles 49 are provided in the drawing, three or more processing liquid supply nozzles 49 may be provided. The processing liquid (phosphoric acid aqueous solution) is supplied to the processing liquid supply nozzles 49 from a vertically extending pipe 49A.

The gas nozzle 60 is in a form of a cylindrical body extending in the X direction (horizontal direction) at a height position lower than the processing liquid supply nozzle 49 within the inner tank 34A. The gas nozzle 60 discharges bubbles of an inert gas (such as nitrogen gas) from a plurality of discharge holes 60D (see FIGS. 3 and 4) perforated in the peripheral surface thereof. Bubbling of the inert gas serves to stabilize the boiling condition of the phosphoric acid aqueous solution within the inner tank 34A. The inert gas is supplied to the gas nozzle 60 from a vertically extending pipe 60A.

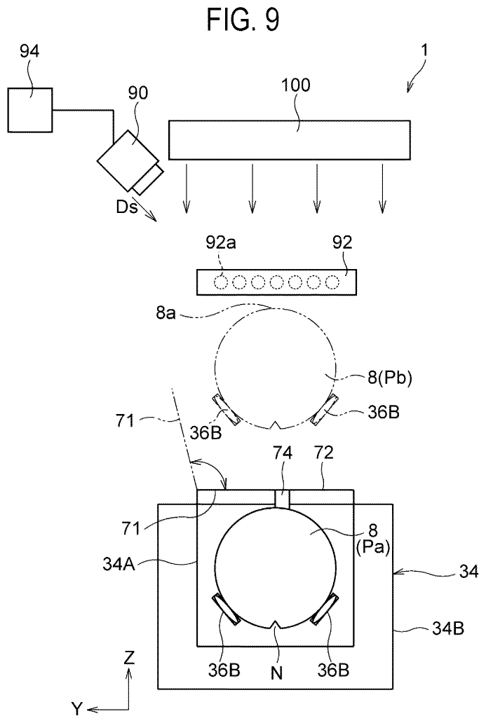

The substrate lifting mechanism 36 includes a support plate 36A, which extends in the vertical direction (Z direction) and is vertically moved by a lifting mechanism 36C, and a pair of substrate support members 36B, which extend in the horizontal direction (X direction), each having one end supported by the support plate 36A (see also FIG. 9). Each substrate support member 36B has a plurality of (e.g., 50 to 52) substrate holding grooves (not illustrated) arranged at intervals in the horizontal direction (X direction). The peripheral edge of the substrate 8 is inserted into each substrate holding groove, and a plurality of substrates are supported by the pair of substrate support members 36B so as to be upright in the Z direction (first direction). In this way, the pair of substrate support members 36B may support a plurality of (e.g., 50 to 52) substrates 8 arranged at intervals in the horizontal direction (X direction) in an upright posture (vertical posture). Such a substrate lifting mechanism 36 is well known in the art, and illustration and description of detailed structures are omitted.

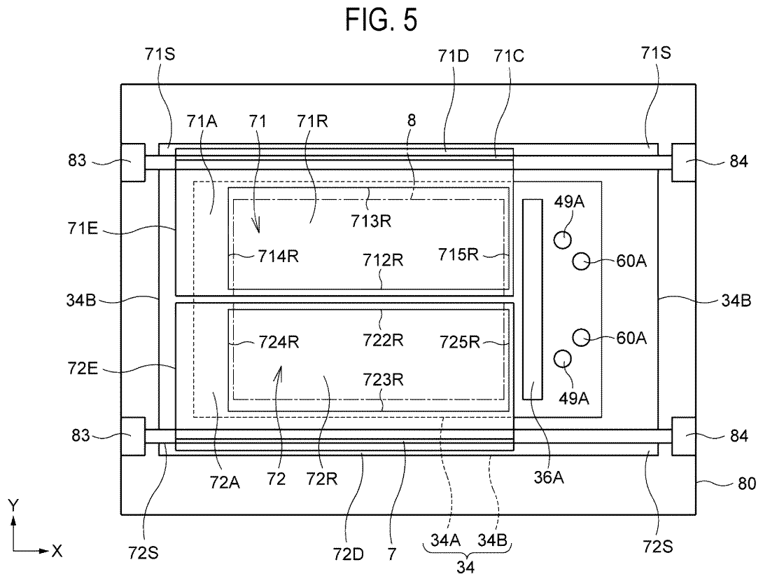

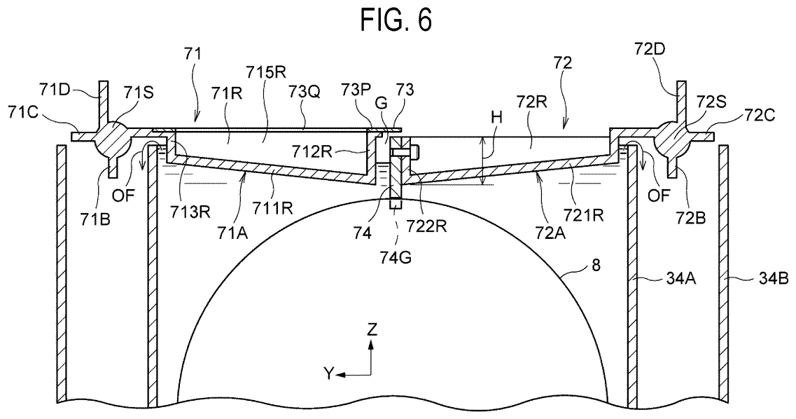

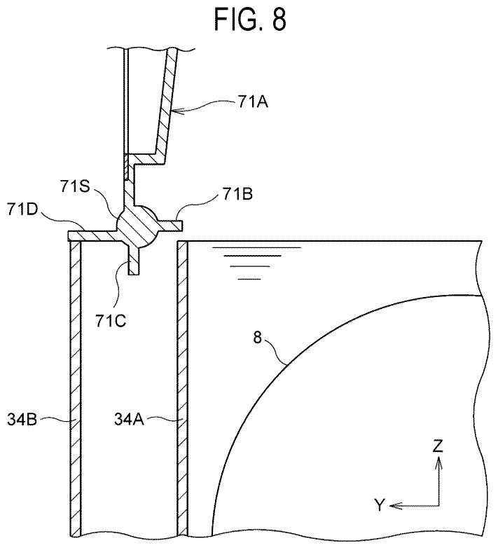

The processing tank 34 is provided with a first lid 71 and a second lid 72 for opening or closing a top opening of the inner tank 34A. The first lid 71 and the second lid 72 are respectively coupled to rotating shafts 71S and 72S extending in the horizontal direction (X direction). The rotating shafts 71S and 72S are connected to a bearing 83 and a rotation actuator 84, which are fixed to the liquid receiving container 80 (see FIGS. 4 and 5). By operating the rotation actuator 84, the first lid 71 and the second lid 72 may rotate (pivot) around respective rotation axes thereof extending in the horizontal direction (X direction) between a closed position (position illustrated in FIGS. 3 and 6), where they cover a first region (left half) and a second region (right half) of the top opening of the inner tank 34A respectively, and an open position (position illustrated in FIG. 8), where they are approximately upright and open the first and second regions of the top opening of the inner tank 34A (see arrows SW1 and SW2 in FIG. 3).

The first lid 71 and the second lid 72 do not cover a region of the top opening of the inner tank 34A where the support plate 36A and pipes 49A and 60A are provided.

During normal operation of the etching processing apparatus 1, the first lid 71 and the second lid 72 are located at the closed position except when loading or unloading the substrates 8 held by the substrate lifting mechanism 36 into or from the inner tank 34A, thereby preventing a drop in the temperature of the phosphoric acid aqueous solution within the inner tank 34A and also preventing the escape of water vapor generated from the boiling phosphoric acid aqueous solution to the outside of the processing tank 34.

The first lid 71 includes a main body 71A that is approximately rectangular when viewed from directly above, first and second splash shields 71B and 71C and a closer 71D extending in the X direction, and a third splash shield 71E extending in the Y direction. Similarly, the second lid 72 includes a main body 72A that is approximately rectangular, first and second splash shields 72B and 72C and a closer 72D extending in the X direction, and a third splash shield 72E extending in the Y direction.

A large rectangular recess 71R is formed in the upper surface of the main body 71A. The recess 71R is defined by a bottom wall 711R and four sidewalls 712R, 713R, 714R and 715R.

When the first lid 71 is at the closed position, a gap is provided between the sidewalls of the inner tank 34A and the sidewalls 712R and 713R facing them in close proximity, so as not to prevent the overflow of the phosphoric acid aqueous solution from the inner tank 34A to the outer tank 34B (see arrow OF in FIG. 6). In addition, although not illustrated, a plurality of V-shaped cutouts are formed at intervals along the upper ends of four sidewalls of the inner tank 34A to facilitate smooth overflow.

The bottom wall 711R of the first lid 71 is inclined such that it becomes higher as it extends away from the second lid 72 in the Y direction (i.e., as it approaches the sidewall of the inner tank 34A in the Y direction). This inclination allows the overflow to proceed smoothly.

Since the phosphoric acid aqueous solution within the inner tank 34A is either in a boiling state or bubbling is applied thereto, droplets of the phosphoric acid aqueous solution may splash out from the inner tank 34A together with the phosphoric acid aqueous solution overflowing from the inner tank 34A to the outer tank 34B. The splashed droplets collide with the first splash shield 71B of the first lid 71 at the closed position, and fall into the space between the sidewall of the inner tank 34A and the sidewall of the outer tank 34B, thereby preventing the droplets from splashing out from the outer tank 34B. It is desirable that the lower end of the first splash shield 71B of the first lid 71 at the closed position is located at least lower than the upper end of the adjacent sidewall of the inner tank 34A.

When the first lid 71 is at the open position, the second splash shield 71C functions in the same way as the first splash shield 71B when the first lid 71 is at the closed position. It is desirable that the lower end of the second splash shield 71C of the first lid 71 at the open position is located at least lower than the upper end of the adjacent sidewall of the inner tank 34A.

When the first lid 71 is at the open position (see FIG. 8), the closer 71D covers the upper side of a region from the rotating shaft 71S to the sidewall of the outer tank 34B among the gap between the upper end of the sidewall of the inner tank 34A and the upper end of the sidewall of the outer tank 34B. The closer 71D guides the liquid adhering to the upper surface of the main body 71A when the first lid 71 is at the closed position (e.g., the liquid dropped from the wet substrate passing above the processing tank 34) into the drain space 81 between the outer tank 34B and the liquid receiving container 80 when the first lid 71 is at the open position, thereby preventing the liquid from being introduced into the outer tank 34B. The liquid introduced into the drain space 81 is discarded from the drain line 82.

The third splash shield 71E is provided to extend above the space between the sidewall of the inner tank 34A and the sidewall of the outer tank 34B on the side farther from the substrate lifting mechanism 36. The third splash shield 71E extends from the rotating shaft 71S in the Y direction along the end rim of the first lid 71 over the entire length of that end rim. The third splash shield 71E functions in the same way as the first splash shield 71B when the first lid 71 is at the closed position. It is desirable that the lower end of the third splash shield 71E of the first lid 71 at the open position is located at least lower than the upper end of the adjacent sidewall of the inner tank 34A.

It may not be necessary to provide a splash shield extending in the Y direction along the end rim of the first lid 71 on the side close to the substrate lifting mechanism 36. This is because the phosphoric acid aqueous solution splashing out in the positive X direction will collide with the support plate 36A of the substrate lifting mechanism 36, the pipes 49A and 60A, and others, and therefore, will hardly reach the outer tank 34B.

The second lid 72 is formed substantially mirror-symmetrically with respect to the first lid 71, and the first and second lids 71 and 72 have substantially the same structure. The only difference between the two lies in the presence or absence of accessory components (a panel 73P and a substrate pressing member 74) described later. Therefore, the description of the configuration and actions of the first lid 71 may be applied to the configuration and actions of the second lid 72. The same alphabetical characters are given to the ends of the reference numbers for corresponding members (members at symmetric positions or members with the same functions) of the first and second lids 71 and 72, and only the first two digits of the reference numbers differ, being “71” or “72”.

As illustrated in FIG. 6, when the first lid 71 and the second lid 72 are at the closed position, the sidewall 712R extending upward from the bottom wall 711R of the first lid 71 and a sidewall 722R extending upward from a bottom wall 721R of the second lid 72 face each other, forming a gap G with a height H between both the sidewalls. Providing the recesses 71R and 72R may prevent an increase in the weight of the first and second lids 71 and 72 that would otherwise result from providing the gap with the height H.

When the lower surface of the main body 71A of the first lid 71 (i.e., the lower surface of the bottom wall 711R) and the lower surface of a main body 72A of the second lid 72 (i.e., the lower surface of the bottom wall 721R), which are at the closed position as illustrated in FIG. 6, are in contact with the surface of the processing liquid within the inner tank 34A, the phosphoric acid aqueous solution, which is boiling or bubbling, may splash out upward from the gap between the first lid 71 and the second lid to the surroundings. However, by providing the gap G with the height H as described above, it becomes difficult for the processing liquid to splash out from the gap G. To achieve this effect, the height H may be set to, for example, approximately 5 cm or more.

When the processing liquid within the inner tank 34A is a phosphoric acid aqueous solution, at least the main bodies 71A and 72A of the first and second lids 71 and 72 are formed of a material that is resistant to the processing liquid, such as quartz. The main bodies 71A and 72A formed of quartz have a risk of chipping or cracking due to collision therebetween. To prevent this, it is desirable to provide a gap between the main bodies 71A and 72A to avoid contact therebetween when the first and second lids 71 and 72 are at the closed position. However, the presence of the gap between the main bodies 71A and 72A may also lead to the risk of the phosphoric acid aqueous solution splashing out from the processing tank 34, especially from the inner tank 34A, through the gap. By providing the gap G with the height H as described above, it is possible to at least significantly prevent the phosphoric acid aqueous solution from splashing out from the gap G.

Further, to facilitate the overflow, the bottom wall 711R (721R) is inclined as described above. When the bottom wall 711R (721R) is brought into contact with the phosphoric acid aqueous solution within the inner tank 34A, the tip of the bottom wall 711R (721R) may be submerged in the phosphoric acid aqueous solution if the sidewall 712R (722R) extending upward from the bottom wall 711R (721R) is absent. However, by providing the sidewall 712R (722R) extending upward from the bottom wall 711R (721R) as described above, it is possible to keep the liquid level of the phosphoric acid aqueous solution lower than the upper end of the sidewall 712R (722R).

As illustrated in FIG. 6, it is desirable to provide an enclosure 73 on either the main body 71A of the first lid 71 or the main body 72A of the second lid 72 (here, the main body 71A) so as to extend to or beyond the tip of the other (here, the main body 72A), thereby covering the gap G from above. By providing the enclosure 73, it is possible to prevent the processing liquid from splashing upward from the gap G. In addition, the enclosure 73 (and the panel 73P) are not illustrated in FIGS. 3 to 5 to avoid confusion in the drawings.

In addition, the height H of the gap G causes processing liquid droplets splashed from the surface of the phosphoric acid aqueous solution within the inner tank 34A to be weakened before they collide with the enclosure 73. Therefore, the processing liquid colliding with the enclosure 73 does not splash out laterally.

As illustrated in FIG. 6, for example, the enclosure 73 may be provided by mounting the panel 73P having an approximately rectangular cutout 73Q, which matches the contour of the recess 71R of the first lid 71, onto the upper surface of the main body 71A of the first lid 71. In this case, the enclosure 73 is formed by an end rim portion of the panel 73P.

As illustrated in FIG. 6, a gap may be provided between the enclosure 73 and the second lid 72 when the first lid 71 and the second lid 72 are at the closed position. Alternatively, the enclosure 73 and the second lid 72 may be in contact with each other when the first lid 71 and the second lid 72 are at the closed position. In this case, the enclosure 73 serves as a seal that closes the upper end of the gap G.

When the enclosure 73 is brought into contact with the second lid 72, it is desirable that the enclosure 73 be formed of a resin material that has no concern to be damaged upon collision with quartz and that is flexible enough not to cause damage to quartz while also having relatively high corrosion resistance, for example, a fluoro-based resin material such as PTFE or PFA.

The enclosure 73 may also be formed integrally with the first lid 71. Further, the enclosure 73 may be omitted. When the enclosure 73 is omitted, it is desirable to set the height H higher than when the enclosure 73 is provided.

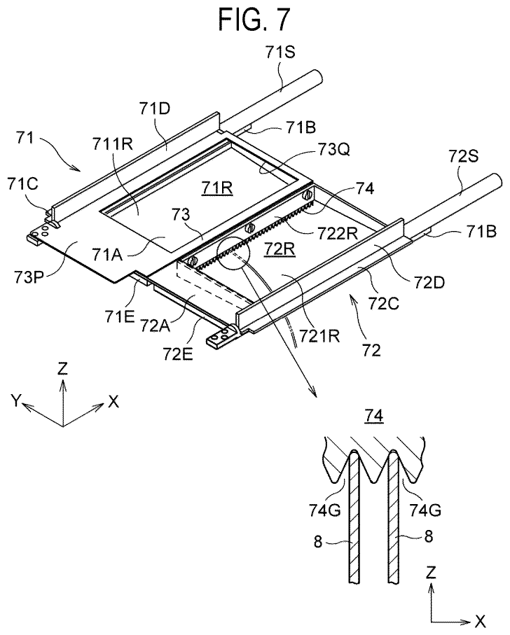

Further, the substrate pressing member 74 is provided on either the main body 71A of the first lid 71 or the main body 72A of the second lid 72 (the tip of the main body 72A of the second lid 72 in the illustrated example). A plurality of substrate holding grooves 74G are formed on the lower surface of the substrate pressing member 74 along the arrangement direction (X direction) of the substrates 8 at the same pitch as the substrate holding grooves 36BG of the substrate support member 36B, which are also arranged in the X direction (see FIG. 7). The peripheral edge of each substrate 8 is accommodated in each substrate holding groove 74G. In addition, it is to be noted that a portion where the lower end (substrate holding groove 74G) of the substrate pressing member 74 is formed is visible in the perspective view of FIG. 7, but it is actually hidden by the bottom wall 721R of the recess 72R.

In the illustrated embodiment, the substrate pressing member 74 is in a form of an elongated panel separate from the second lid 72 and is fixed to the main body 72A of the second lid 72 by screwing. Alternatively, the substrate pressing member 74 may be formed integrally with the second lid 72. In either case, the substrate pressing member 74 constitutes a part of the sidewall 722R of the main body 72A of the second lid 72.

When the substrates 8 are being processed, the substrate pressing member 74 provided on the second lid 72, which is at the closed position, engages with the substrates 8 supported by the substrate support member 36B to prevent or minimize the upward displacement of the substrates 8. Therefore, even if the processing liquid is discharged at a high flow rate from the processing liquid supply nozzle 49, or even if the boiling level of the processing liquid within the inner tank 34A becomes high, or even if nitrogen gas bubbling is performed vigorously, there is no risk that the substrates 8 fall off from the substrate support member 36B.

FIG. 9 is a schematic diagram illustrating an example of a camera (image capturer) 90 and an illuminator 92, which are arranged near the processing tank 34.

The etching processing apparatus (substrate liquid processing apparatus) 1 of the present embodiment is provided with the camera 90 and the illuminator 92.

The camera 90 acquires a captured image of the outer peripheral end faces 8a of the plurality of substrates 8 (lot) (APEX (outermost edges of the substrates 8) and the vicinity thereof) held by the substrate support member 36B, and transmits the captured image to an image processor 94. The camera 90 simultaneously captures an image of all of the plurality of substrates 8 included in the lot, thereby acquiring captured image data of the respective substrates 8 held by the substrate support member 36B.

The captured image includes an image of only a part of the outer periphery of each substrate 8 (the upper outer periphery in this example), but includes an image of the outer peripheral end face 8a that has a range greater than twice the range of the notch N on the outer periphery of each substrate 8. Further, in addition to the image of the substrate 8, the captured image also includes an image of an apparatus component other than the substrate 8 (e.g., an image of the substrate support member 36B (background image)).

The camera 90 of the present embodiment acquires a captured image of the outer peripheral end faces 8a of the plurality of substrates 8 illuminated by light from the illuminator 92. The camera 90 in this example performs image capturing of the plurality of substrates 8 supported by the substrate support member 36B in a state where the substrates 8 are located outside the processing tank 34, thereby acquiring a captured image of the plurality of substrates 8.

In other words, the substrate support member 36B is moved by the lifting mechanism 36C (support mover; see FIG. 3) as described above, thereby allowing the plurality of supported substrates 8 (lot) to be located either at a processing position Pa or a retreat position Pb. At the processing position Pa, the plurality of substrates 8 are located within the processing tank 34 and are immersed in the processing liquid stored within the processing tank 34 to undergo liquid processing (etching processing). On the other hand, at the retreat position Pb, the plurality of substrates 8 are located outside the processing tank 34. In the example illustrated in FIG. 9, the retreat position Pb is set directly above the processing position Pa, and the plurality of substrates 8 located at the processing position Pa are moved upward (in the Z direction) together with the substrate support member 36B, thereby being located at the retreat position Pb.

The camera 90 of the present embodiment performs image capturing while the substrate support member 36B and the plurality of substrates 8 are stationary, but may perform image capturing while the substrate support member 36B and the plurality of substrates 8 are moving. An image capturing direction Ds of the camera 90 when acquiring the captured image is not limited, but the image capturing direction Ds of the present embodiment is inclined relative to the Z direction (first direction) (i.e., forming an angle greater than 0 degrees and less than 90 degrees with respect to the Z direction). The image capturing direction Ds in this example includes a component along the extension direction (Y direction) of each substrate 8.

A fan filter unit (FFU) 100 is arranged above the camera 90, and the downflow of clean air generated by the fan filter unit 100 prevents the upward flow of gas or mist generated from the processing liquid within the processing tank 34. The camera 90 may be provided to overlap the fan filter unit 100 in the Z direction (height direction), but in the example illustrated in FIG. 9, the camera 90 is provided so as not to overlap the fan filter unit 100 in the Z direction.

A cover (not illustrated) that covers at least a part of the camera 90 may also be provided, and a shielding gas may be introduced into an inner side of the cover to protect the camera 90 arranged inside the cover from the gas or mist generated from the processing liquid.

The illuminator 92 emits light onto the outer peripheral end faces 8a of the plurality of substrates 8 supported by the substrate support member 36B (particularly onto a portion of the outer peripheral end faces 8a being image-captured by the camera 90 (an upper portion in this example).

The illuminator 92 of the present embodiment is located between the camera 90 and the outer peripheral end surfaces (particularly the upper outer peripheral end faces) 8a of the plurality of substrates 8. The illuminator 92 illustrated in FIG. 9 is located below the camera 90 and above and in the vicinity of the upper ends of the substrates 8 arranged at the retreat position Pb, and extends in the Y direction (horizontal direction) perpendicular to the Z direction. When the plurality of substrates 8, which serve as an image capturing target, are arranged at the retreat position Pb, the light emitted from the illuminator 92 is reflected by the outer peripheral end faces 8a and enters the camera 90 as image capturing light, thereby allowing image capturing to be performed.

The illuminator 92 located as described above emits light in a partial certain-length range or the entire range along the extension direction toward the deeper side of the page. Therefore, when the camera 90 performs image capturing of the outer peripheral end faces 8a of the plurality of substrates 8, the direction of illumination from the illuminator 92 toward the outer peripheral end faces 8a of the plurality of substrates 8 is inclined relative to the Z direction (first direction) (extending toward the deeper side of the page and downward in FIG. 9). The direction of light emitted from the illuminator 92 in this example includes a component along the arrangement direction (X direction) of the plurality of substrates 8.

The direction in which the illuminator 92 extends (Y direction) coincides with the direction in which each of the plurality of substrates 8 as an image capturing target extends, and the range of the outer peripheral end face 8a of each substrate 8 illuminated by the light from the illuminator 92 has a certain length in the Y direction. Therefore, the outer peripheral end face 8a of each substrate 8 as an image capturing target appears as a linear image in the captured image.

In addition, the illuminator 92 may have any form and configuration, and may include, for example, one or more linear light sources and/or point light sources. Such light sources of the illuminator 92 may be, for example, fluorescent lamps or light emitting diodes (LEDs).

As an example, the illuminator 92 may include a plurality of point light sources (see reference numeral “92a” in FIG. 9), and the plurality of point light sources 92a may be arranged in a line along the extension direction (Y direction) of the illuminator 92. In this case, the camera 90 acquires a captured image of the outer peripheral end faces 8a of the plurality of substrates 8 illuminated by light emitted from each of the plurality of point light sources 92a.

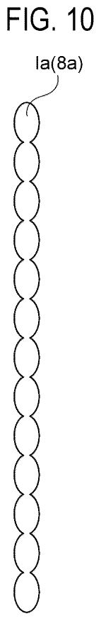

In the captured image obtained under such illumination by the plurality of point light sources 92a arranged in a line, an image portion 1a of the outer peripheral end face 8a of each substrate 8 tends to be represented, at least partially, as a plurality of interconnected light spot images as illustrated in FIG. 10. The fact that the image portion 1a of the outer peripheral end face 8a in the captured image has a characteristic shape may be advantageous for image processing to derive the position, range and other characteristics of the outer peripheral end face 8a in the captured image.

The above-described positional relationship between the camera 90, the illuminator 92, and the plurality of substrates 8 (particularly the plurality of substrates 8 arranged at the retreat position Pb (image capturing position)) is advantageous in acquiring the captured image of the outer peripheral end face 8a of each substrate 8 in a form suitable for image processing described later.

In addition, the plurality of substrates 8 (lot) as an image capturing target may be provided to be movable along with the substrate support member 36B, but the camera 90 and the illuminator 92 may be fixedly supported by, e.g., a support frame, or may be movably provided. When the camera 90 and/or the illuminator 92 are movably provided, the camera 90 and/or the illuminator 92 may be moved by a dedicated moving mechanism (not illustrated) driven under the control of the controller 7.

The image processor 94 may be connected to the camera 90 in a wired or wirelessly manner to perform image processing on the captured image transmitted from the camera 90, and may make various determinations based on the results of the image processing. The image processor 94 may be configured with the controller 7, or may be configured with an arithmetic processing unit (not illustrated) provided separately from the controller 7.

The image processor 94 of the present embodiment performs a comparison between the captured image of the outer peripheral end faces 8a of the plurality of substrates 8 before immersion in the processing liquid and the captured image of the outer peripheral end faces 8a of the plurality of substrates 8 after immersion in the processing liquid. Then, the image processor 94 detects a positional misalignment between the plurality of substrates 8 before immersion in the processing liquid and the plurality of substrates 8 after immersion in the processing liquid based on the results of the comparison, and makes a determination depending on the positional misalignment.

By performing image processing on the captured image, the image processor 94 is capable of identifying, for example, a reflected image of the upper outer peripheral end face 8a of the substrate 8 included in the captured image, thereby acquiring information on the installation of the substrate 8 (e.g., position information on a substrate image region corresponding to the range of the substrate 8 in the captured image). Further, the image processor 94 is capable of determining whether the difference between the position of each substrate 8 before processing with the processing liquid within the processing tank 34 and the position of each substrate 8 after processing is within an allowable range, thereby determining whether each substrate 8 after processing is placed at an appropriate position.

In addition, a specific example of image processing performed by the image processor 94 will be described later, but the content of image processing is not limited thereto. In other words, the image processor 94 is capable of performing arbitrary arithmetic processing to derive arbitrary information from the captured image.

### [Substrate Liquid Processing Method (Etching Processing Method)]

Next, a substrate liquid processing method (etching processing method) performed by the above-described etching processing apparatus (substrate liquid processing apparatus) 1 will be described by way of example. Although the following description will be given of an etching processing method, the technique described below may also be applied to other substrate liquid processing methods performed by other substrate liquid processing apparatuses (e.g., the cleaning processing apparatus 25 (see FIG. 1)).

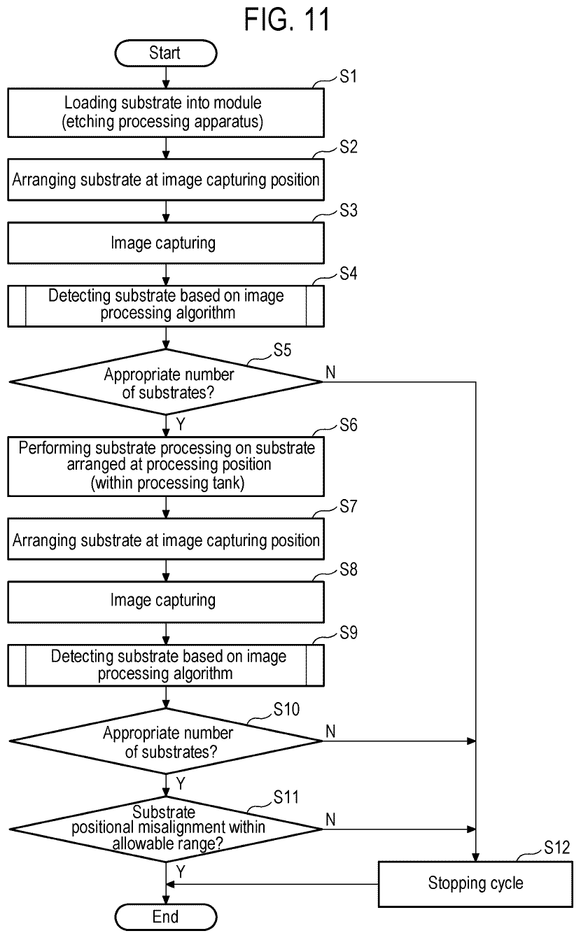

FIG. 11 is a flowchart illustrating an example of a substrate liquid processing method. The substrate liquid processing method illustrated in FIG. 11 is performed by appropriately driving various devices under the control of the controller 7.

The lot of the plurality of substrates 8 is loaded into a module of the etching processing apparatus 1 together with the substrate support member 36B (S1 in FIG. 11), and is then arranged at an image capturing position (in this example, the retreat position Pb (see FIG. 9)) (S2), where an image of the substrates is captured by the camera 90 (S3). In other words, before the plurality of substrates 8 supported in an upright position and arranged at intervals by the substrate support member 36B are immersed in the processing liquid within the processing tank 34, a captured image of the outer peripheral end faces 8a of the plurality of substrates 8 is acquired.

The captured image acquired in this manner is sent from the camera 90 to the image processor 94 and are subjected to image processing by the image processor 94 (S4). In this image processing, the plurality of substrates 8 are detected from the captured image based on an image processing algorithm, and, for example, position information (e.g., coordinate information) on the entire lot of the plurality of substrates 8 and position information on each substrate 8 may be acquired.

The image processor 94 determines, for example, whether the number of substrates 8 (i.e., the number of substrates 8 included in the lot, which serve as a liquid processing target) arranged at the retreat position Pb (image capturing position) is appropriate based on the results of detection by the image processing (S5).

The image processor 94 may acquire information on the expected number of substrates 8 included in the target lot from the controller 7 based on information for lot formation (e.g., the number of substrates set by a request command), while acquiring the actual number of substrates 8 included in the captured image by image processing. The image processor 94 may determine whether the number of substrates 8 included in the liquid processing target lot is appropriate by comparing the expected number and actual number of substrates 8 in the lot acquired in this manner.

If it is determined that the number of substrates 8 included in the processing target lot is not appropriate (“N” in S5), the cycle of the substrate liquid processing method is stopped (S12), and the substrate liquid processing method for that lot is terminated. When the cycle is stopped in this way, the etching processing apparatus 1 (and thus the substrate liquid processing system 1A) may perform any arbitrary processing, such as issuing an alarm to a user (e.g., an operator), under the control of the controller 7.

When the cycle is stopped in this way before liquid processing is performed on the processing target lot (the plurality of substrates 8), the subsequent processing (S6 to S11) of the substrate liquid processing method is skipped, and as a result, liquid processing (S6) is not performed for the processing target lot. The controller 7 may control various devices so that the substrates 8 of the lot that did not undergo liquid processing are handled separately from the substrates 8 that have undergone liquid processing, for example, in the carrier stock 13 (see FIG. 1).

On the other hand, if it is determined that the number of substrates 8 included in the liquid processing target lot is appropriate (“Y” in S5), the plurality of substrates 8 supported by the substrate support member 36B are positioned within the processing tank 34 so as to be immersed in the processing liquid within the processing tank 34. Thus, the plurality of substrates 8 (lot) are arranged at the processing position Pa together with the substrate support member 36B and undergo liquid processing (S6).

After the plurality of substrates 8 remain immersed in the processing liquid for a certain period of time, the substrates 8 are moved out of the processing tank 34 together with the substrate support member 36B so as to escape from the processing liquid, and are arranged at the image capturing position (retreat position Pb) (S7). In this way, when the plurality of substrates 8 escape from the processing liquid, the liquid processing for the substrates 8 is terminated.

Then, an image of the plurality of substrates 8 is captured by the camera 90 while the substrates 8 being arranged at the image capturing position (retreat position Pb) (S8). In other words, after the plurality of substrates 8 supported in an upright position and arranged at intervals by the substrate support member 36B are immersed in the processing liquid within the processing tank 34, a captured image of the outer peripheral end faces 8a of the plurality of substrates 8 is acquired.

The captured image acquired in this manner is sent from the camera 90 to the image processor 94 and is subjected to image processing by the image processor 94 (S9). In this image processing, the plurality of substrates 8 is detected from the captured image based on an image processing algorithm, and, for example, position information on the entire lot of the plurality of substrates 8 and position information on each substrate 8 may be acquired.

In addition, the image processing (S9) on the captured image of the plurality of substrates 8 after immersion in the processing liquid and the image processing (S4) on the captured image of the plurality of substrates 8 before immersion in the processing liquid may include common processing processes, and may also include different processing processes.

Similar to the above-described processing step S5, the image processor 94 determines, for example, whether the number of substrates 8 arranged at the image capturing position is appropriate based on the results of detection by image processing (S10).

Then, if it is determined that the number of substrates 8 included in the processing target lot is not appropriate (“N” in S10), the cycle of the substrate liquid processing method is stopped (S12), and the substrate liquid processing method for that lot is terminated. When the cycle is stopped in this way, an alarm may be issued, or other arbitrary processing may be performed.

On the other hand, if it is determined that the number of substrates 8 as the liquid processing target is appropriate (“Y” in S10), the image processor 94 makes a determination depending on a positional misalignment between the plurality of substrates 8 before and after immersion in the processing liquid (S11).

In other words, a determination depending on a positional misalignment of each substrate 8 before and after liquid processing is made based on a comparison between a captured image of the outer peripheral end faces 8a of the plurality of substrates 8 before immersion in the processing liquid and a captured image of the outer peripheral end faces 8a of the plurality of substrates 8 after immersion in the processing liquid.

For example, the difference between the position of each substrate 8 before immersion in the processing liquid and the position of each substrate 8 after immersion in the processing liquid is obtained based on the position coordinates of each substrate 8 obtained as a result of image processing, and it is then determined whether the difference falls within an allowable range (e.g., whether the difference is equal to or less than a determination threshold set by the user). If it is determined that the substrate 8 having a position difference exceeding the allowable range before and after processing is included in the processed lot (the plurality of substrates 8) (“N” in S11), the cycle of the substrate liquid processing method is stopped (S12), and the substrate liquid processing method for that lot is terminated. When the cycle is stopped in this way, an alarm may be issued, or other arbitrary processing may be performed. On the other hand, if it is determined that the position difference before and after processing for all of the substrates 8 in the processed lot falls within the allowable range (“Y” in S11), it is determined that all of the substrates 8 included in that lot have undergone liquid processing under appropriate positions and postures, and the substrates 8 are then transferred to the carrier stock 13 (see FIG. 1).

The above-described series of processing (S1 to S12) are performed on each lot (the plurality of substrates 8) that needs to be processed in the etching processing apparatus 1.

### [Image Processing Method]

Next, an image processing method performed by the image processor 94 in the above-described substrate liquid processing method (etching processing method) will be described by way of example. The image processing method described below is merely an example, and may include any arbitrary image processing process, in addition to or instead of one or more of image processing processes described below.

In FIG. 11 described above, the image processing method performed by the image processor 94 includes steps of acquiring captured images of the plurality of substrates 8 (lot) before and after liquid processing from the camera 90 (S3 and S8), and steps of making a determination depending on a positional misalignment of the plurality of substrates 8 (S4, S5, and S9 to S11).

In particular, to make a determination depending on a positional misalignment of the plurality of substrates 8, it is necessary to obtain position information (such as position coordinates) of each substrate 8 in the captured images before and after processing. However, acquiring such position information on each substrate 8 from the captured images with high accuracy while minimizing computational load required for image processing is not always easy.

As a result of repeated trial and error, the inventors of the present disclosure have newly determined an image processing method (image processing process) that is effective in accurately acquiring position information on the plurality of substrates 8 included in the processing target lot from the captured images while minimizing computational load. An example of such an image processing method will be described below.

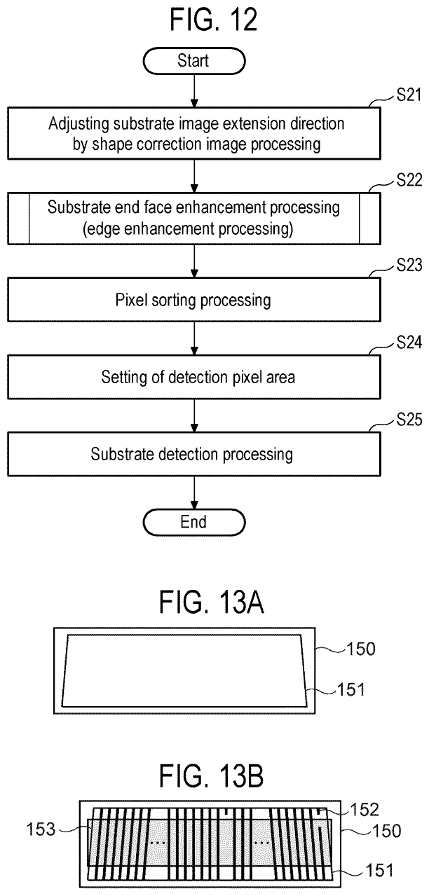

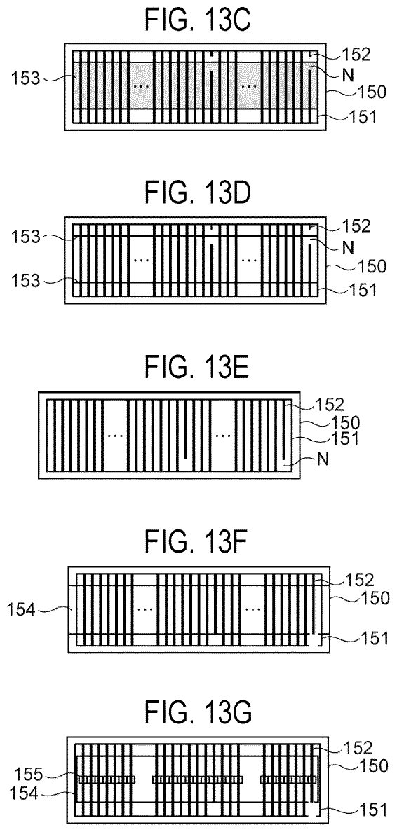

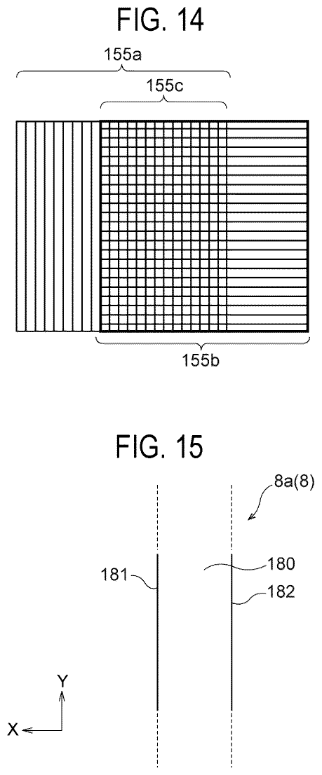

FIG. 12 is a flowchart illustrating an example of an image processing method. FIGS. 13A to 13G illustrate examples of a partial region of a captured image 150 (including a substrate image region 151) and are conceptual diagrams illustrating the image processing method illustrated in FIG. 12. FIG. 14 is a diagram illustrating an example of a comparison between a captured image before liquid processing and a captured image after liquid processing.

As illustrated in FIG. 13A, the image processor 94 determines the substrate image region 151, which is a region in the captured image 150 including at least a part of an image portion (substrate image 152) of the outer peripheral end faces 8a of the plurality of substrates 8.

When a single camera 90 captures images of the plurality of substrates 8 (lot) arranged in the X direction, the images of the substrates 8 located farther from the optical axis of the camera 90 tend to be more distorted. In this example, as illustrated in FIG. 13B, the images (substrate images 152) of the substrates 8 located farther from the center of the captured image 150 in the substrate arrangement direction (left-right direction in FIG. 13B) tend to exhibit a greater inclination. Therefore, the substrate image region 151 in this example is determined taking into consideration distortion (inclination) in the images of the substrates 8, and specifically, has a trapezoidal shape as illustrated in FIG. 13A.

A specific method of determining the substrate image region 151 is not limited, and for example, the substrate image region 151 may be determined based on a captured image of a test lot before liquid processing of the liquid processing target lot (the plurality of substrates 8). For example, image capturing may be performed with test substrates arranged at respective substrate holding locations (the above-described substrate holding grooves (slots)) at both ends of the substrate support member 36B. In this case, the position coordinates of the upper and lower ends (i.e., the position coordinates of the upper left, upper right, lower left, and lower right ends) of an image of each of the test substrates (particularly, the outer peripheral end faces) at both the left and right ends as derived from the captured image may be set as four corner coordinates of the substrate image region 151. In addition, when the horizontal length (width) of the image of the outer peripheral end faces of the test substrate is relatively large (see FIG. 10), the corner coordinates of the substrate image region 151 may be set based on the center position of the image in the horizontal direction (e.g., the center position of the elliptical light spot images illustrated in FIG. 10).

Then, as illustrated in FIG. 13B, the image processor 94 applies the substrate image region 151 to the captured image 150 of the plurality of substrates 8 (lot) as a processing target. All images of the plurality of processing target substrates 8 appearing in the captured image 150 are located within the substrate image region 151. In addition, the image of each substrate 8 in the captured image 150 does not need to be located entirely within the substrate image region 151, and may be partially located outside the substrate image region 151.

The captured image 150 at the stage where the substrate image region 151 is applied thereto includes not only the substrate image region 151 but also an image of components other than the substrates 8. In the example illustrated in FIG. 13B, a background image 153, which corresponds to an image of apparatus components located below (the deeper side of the page of FIG. 13B) the plurality of substrates 8 being image-captured, also appears in the captured image 150.

Then, as illustrated in FIG. 13C, the image processor 94 performs processing (shape correction image processing) of converting the overall shape of the substrate image region 151 from a trapezoid to a rectangle (S21 in FIG. 12). Through this processing, distortion in the image (particularly the substrate image 152) within the substrate image region 151 is corrected, and the extension direction of each substrate image 152 (substrate image extension direction) is adjusted to be substantially perpendicular to the arrangement direction of the images of the plurality of substrates 8 (the left-right direction (X direction) in FIG. 13C).

In addition, in this example, such shape correction image processing is performed prior to edge enhancement processing (S22) described later, but may also be performed after or simultaneously with the edge enhancement processing. However, if the shape correction image processing is performed after the edge enhancement processing, it is desirable that the shape correction image processing is performed before pixel sorting processing (S23) described later.

Thereafter, as illustrated in FIG. 13D, the image processor 94 performs the edge enhancement processing (substrate end face enhancement processing) on at least the substrate image region 151 of the captured image 150 to emphasize an image of the outer peripheral end face 8a of each substrate 8 (S22).

In the captured image 150 after the edge enhancement processing, the image of the outer peripheral end face 8a of each substrate 8 remains as the substrate image 152, while an image of apparatus components other than the substrates 8 (background image 153) is made less prominent. In the example illustrated in FIG. 13D, an edge portion of the background image 153 remains in the captured image 150 after the edge enhancement processing, but an intermediate portion between the edges of the background image 153 has become less prominent. In addition, the substrate image 152 representing each substrate 8 is represented by a single line in the example illustrated in FIG. 13D, but as a result of the above-described substrate end face enhancement processing, the substrate image 152 may be represented by multiple lines (e.g., two lines representing the respective end face edges (see reference numerals “181” and “182” in FIG. 15).

In addition, the edge enhancement processing in step S22 may be performed by applying an edge enhancement filter to at least the substrate image region 151 of the captured image 150, but a specific processing content of the edge enhancement processing is not limited.

Thereafter, as illustrated in FIG. 13E, the image processor 94 performs pixel sorting processing for rearranging pixels included in image data of the substrate image region 151 after the edge enhancement processing (S23).

The image data subjected to the pixel sorting processing includes multiple pixel sets arranged in a direction perpendicular to the direction in which the image portion (substrate image 152) of each substrate 8 extends (substrate image extension direction). Here, the term “pixel set” includes multiple pixels arranged in a line in the vertical direction (Y direction) in FIG. 13E. The image data of the substrate image region 151 is composed of a collection of multiple “pixel sets” arranged in the left-right direction (X direction) in FIG. 13E.

The pixel sorting processing of the present embodiment rearranges multiple pixels included in each pixel set, which are arranged in the substrate image extension direction (Y direction), according to the magnitude of brightness values thereof. After undergoing the pixel sorting processing, each pixel set is arranged in the descending order of the brightness values from one end to the other end (e.g., from the top to the bottom in FIG. 13E). As a result, pixels with extremely high brightness values (bright pixels) are gathered at one end of each pixel set (the top in the example illustrated in FIG. 13E), while pixels with extremely low brightness values (dark pixels) are gathered at the other end of each pixel set (the bottom in the example illustrated in FIG. 13E).

In general, a noise image may have high pixel values which are extremely bright, whereas an image of the notch N of each substrate 8 may have low pixel values which are extremely dark. Accordingly, in the substrate image 152 after the pixel sorting processing, pixels constituting the noise image are gathered at one end of in the substrate image extension direction (the top in FIG. 13E), while pixels constituting the notch image are gathered at the other end in the substrate image extension direction (the bottom in FIG. 13E). On the other hand, in the substrate image 152 after the pixel sorting processing, pixels constituting a normal portion image of the outer peripheral end face 8a of the substrate 8 are gathered at the center in the substrate image extension direction.

In this way, the pixel sorting processing allows irregular pixels with extremely high or low brightness values in each substrate image 152 to be separated from normal pixels constituting the normal portion image of the outer peripheral end face 8a of the substrate 8.

Thereafter, as illustrated in FIG. 13F, the image processor 94 sets a detection pixel area 154 in the captured image 150 (particularly in the substrate image region 151) after the pixel sorting processing (S24).

The detection pixel area 154 is set to include multiple pixels at the center in the substrate image extension direction of the substrate image 152 (particularly the substrate image 152 in the substrate image region 151) for all of the substrates 8 in the captured image, while excluding multiple pixels at both ends in the substrate image extension direction. In other words, the detection pixel area 154 is set so as to include “normal pixels constituting the normal image of the outer peripheral end face 8a of the substrate 8” of the substrate image 152 after the pixel sorting processing, while excluding as many “irregular pixels” as possible from the detection pixel area 154.

Although a method of determining the detection pixel area 154 is not limited, for example, the detection pixel area 154 may be set such that a predetermined proportion of pixels determined by using the center of the substrate image region 151 in the substrate image extension direction (Y direction) as a reference is included in the detection pixel area 154. As an example, the detection pixel area 154 may be set such that the length of the detection pixel area 154 in the substrate image extension direction (Y direction) is ½ (50%) of the total length of the substrate image region 151 in the substrate image extension direction.

Thereafter, as illustrated in FIG. 13G, the image processor 94 performs substrate detection processing to detect each substrate 8 from each substrate image 152 in the detection pixel area 154 (S25).

For example, it is possible to detect the presence or absence of an image of the corresponding substrate 8 based on the overall data of each substrate image 152 (overall pixel data of each substrate image 152) in the detection pixel area 154. As an example, in the detection pixel area 154, a representative value (e.g., an average value) of pixel values of multiple pixels (pixel set) arranged in the substrate image extension direction (Y direction) may be handled as the pixel value of the pixel set. Further, it is possible to detect the position of the corresponding substrate 8 (particularly the position in the X direction (left-right direction in FIG. 13G)) based on data on the center of each substrate image 152 in the detection pixel area 154 (data on one or more pixels located at the center of each substrate image 152 in the substrate image extension direction).

Thus, according to this example, a determination is made based on a comparison between the substrate image region 151 after the pixel sorting processing of the outer peripheral end faces 8a of the plurality of substrates 8 before immersion in the processing liquid and the substrate image region 151 after the pixel sorting processing of the outer peripheral end faces 8a of the plurality of substrates 8 after immersion in the processing liquid. In the example illustrated in FIG. 13G, a substrate position marker image 155 having a predetermined shape (in this example, a rectangle such as 10 pixels×10 pixels) is superimposed on the corresponding substrate image 152 at the detected image position of each substrate 8 (particularly the center position in the substrate image extension direction).

The image processor 94 performs a series of image processing, as illustrated in FIGS. 12 to 13G described above, on each of the “captured image 150 of the outer peripheral end faces 8a of the plurality of substrates 8 before immersion in the processing liquid” and the “captured image 150 of the outer peripheral end faces 8a of the plurality of substrates 8 after immersion in the processing liquid”. Then, the image processor 94 performs a comparison based on a substrate position marker image 155a of the “captured image 150 of the outer peripheral end faces 8a of the plurality of substrates 8 before immersion in the processing liquid” and a substrate position marker image 155b of the “captured image 150 of the outer peripheral end faces 8a of the plurality of substrates 8 after immersion in the processing liquid.”

As for the substrate 8 with no positional misalignment (particularly positional misalignment in the substrate arrangement direction (X direction)) before and after liquid processing, the substrate position marker image 155a before liquid processing and the substrate position marker image 155b after liquid processing completely match. In other words, a marker overlap region 155c (see FIG. 14), where the marker images 155a and 155b before and after liquid processing overlap each other, has the maximum area (i.e., 100% of the area of the marker image 155). On the other hand, as illustrated in FIG. 14, as for the substrate 8 with a greater positional misalignment (particularly positional misalignment in the substrate arrangement direction (X direction)) before and after liquid processing, the area of the marker overlap region 155c decreases.

Accordingly, the image processor 94 may set a threshold for the area of the marker overlap region 155c, and may determine the positional misalignment of each substrate 8 based on whether the actual area of the marker overlap region 155c of each substrate 8 is equal to or greater than the threshold. In other words, if the area of the marker overlap region 155c is equal to or greater than the threshold (e.g., 70% of the area of the marker image 155), the positional misalignment of the substrate 8 may be determined to be within the allowable range. On the other hand, if the area of the marker overlap region 155c is less than the threshold, the positional misalignment of the substrate 8 may be determined to exceed the allowable range.

Next, a specific example of the above-described edge enhancement processing (substrate end face enhancement processing; see S22 in FIG. 12) will be described.

FIG. 15 is a partially enlarged plan view schematically illustrating an example of the outer peripheral end face 8a of the substrate 8.

Although the width of the outer peripheral end face 8a of each substrate 8 (particularly the length in the substrate arrangement direction (X direction)) is generally small, the outer peripheral end face 8a has a certain width when considered based on pixels. That is, as illustrated in FIG. 15, the outer peripheral end face 8a of the substrate 8 includes elongated linear first end face edge 181 and second end face edge 182, and an end face region 180, which is sandwiched between both the end face edges 181 and 182 and occupies a width larger than both the end face edges 181 and 182.

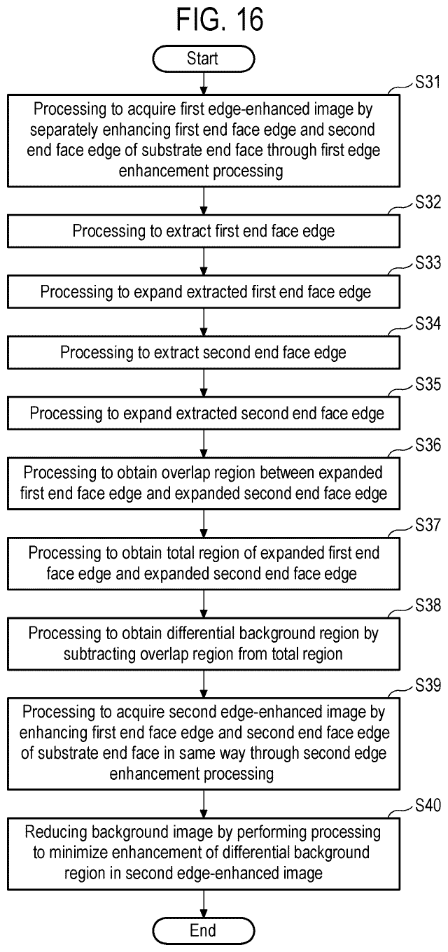

FIG. 16 is a flowchart illustrating an example of an edge enhancement processing method (substrate end face enhancement processing method) executed by the image processor 94.

In the edge enhancement processing of this example, first, first edge enhancement processing is performed on the captured image (original image) (S31 in FIG. 16). Thus, in the image (substrate image 152) of the outer peripheral end face 8a of each substrate 8, image portions of the first end face edge 181 and the second end surface edge 182 are separately enhanced, acquiring a first edge-enhanced image.

In general, brightness in an edge image portion changes relatively significantly, resulting in a transition from a bright image to a dark image or vice versa across the edge image portion. Therefore, when performing image differentiation processing, an image differential value often exhibits a peak in either the positive or negative side in the edge image portion.

The first edge enhancement processing in this step includes, for example, an X-direction differentiation processing on the captured image (grayscale version of the original image). At this time, the X-direction differentiation processing is applied to the pixel values (particularly, pixel values represented by grayscale values corresponding to brightness) of multiple pixels constituting the captured image.

In the first edge-enhanced image obtained in this manner, for example, the first end face edge 181, where the pixel differential value exhibits a peak on the positive side, is represented as a sequence of white pixels with high pixel values (brightness values). On the other hand, for example, the second end face edge 182, where the pixel differential value exhibits a peak on the negative side, is represented as a sequence of black pixels with low pixel values (brightness values) in the first edge-enhanced image. Then, in the first edge-enhanced image, a gray region between the white pixels and the black pixels represents the outer peripheral end face 8a (particularly the end face region 180) of the substrate 8, which appears relatively uniformly bright in the captured image and exhibits little change in brightness.

Thereafter, image processing is performed to extract the image portion of the first end face edge 181 from the first edge-enhanced image (S32). Specifically, only the white pixels with high pixel values in the first edge-enhanced image are extracted. In practice, this image processing extracts not only the image portion of the first end face edge 181 but also a bright image portion that is an image portion representing other apparatus components (background image) and has pixel values equal to or greater than those of the image portion of the first end face edge 181 in the first edge-enhanced image.

Thereafter, image processing (expansion processing) is performed to expand the extracted image portion (image portion of the first end face edge 181) in the first edge-enhanced image (S33). In this expansion processing, a target image portion (image portion of the first end face edge 181) is expanded in the X direction corresponding to the width direction of the outer peripheral end face 8a of each substrate 8 (i.e., the substrate arrangement direction). The degree of expansion at this time is not limited, but it is desirable to perform expansion processing to such an extent that the expanded image portions of the first end face edge 181 and the second end face edge 182 (see S33 and S35 described later) do not overlap each other between different substrates 8.

On the other hand, image processing is performed to extract the image portion of the second end face edge 182 from the first edge-enhanced image (S34). Specifically, only the black pixels with low pixel values in the first edge-enhanced image are extracted. In practice, this image processing extracts not only the image portion of the second end face edge 182 but also a dark image portion that is an image portion representing other apparatus components (background images) and has pixel values equal to or less than those of the image portion of the second end face edge 182.

Thereafter, image processing (expansion processing) is performed to expand the extracted image portion (image portion of the second end face edge 182) in the first edge-enhanced image (S35). In this expansion processing, a target image portion (image portion of the second end face edge 182) is expanded in the X direction corresponding to the width direction of the outer peripheral end face 8a of each substrate 8 (i.e., the substrate arrangement direction). The degree of expansion at this time is not limited, but it is desirable to perform expansion processing to such an extent that the expanded image portions of the first end face edge 181 and the second end face edge 182 (see S33 and S35) do not overlap each other between different substrates 8.

Then, in the first edge-enhanced image, image processing is performed to obtain an overlap region between the image portion of the first end face edge 181 after expansion processing (expanded first end face edge) and the image portion of the second end face edge 182 after expansion processing (expanded second end face edge) (S36). Herein, pixels constituting the overlap region mean pixels belonging to both the expanded first end face edge and the expanded second end face edge.

Further, in the first edge-enhanced image, image processing is performed to determine the total region of the image portion of the first end face edge 181 after expansion processing (expanded first end face edge) and the image portion of the second end face edge 182 after expansion processing (expanded second end face edge) (S37).

Herein, pixels constituting the total region mean pixels belonging to at least one of the expanded first end face edge and the expanded second end face edge. Therefore, the total region includes pixels that belong only to the expanded first end face edge, pixels that belong only to the expanded second end face edge, and pixels that belong to both the expanded first and second end face edges.

Then, in the first edge-enhanced image, image processing is performed to obtain a differential region between the total region (see S37) and the overlap region (see S36) (S38). The differential region is defined as a differential background region representing a region other than the substrate 8. It is desirable that the above-described expansion processing (S33 and S35) is performed to ensure that the differential region (differential background region) exists, for example, between adjacent substrates 8. Therefore, it is desirable for each of the expanded first end face edge and the expanded second end face edge to cover the entirety of the end face region 180, the first end face edge 181, and the second end face edge 182 of the corresponding substrate 8.

After obtaining the differential background region as described above, second edge enhancement processing is performed on the captured image (original image) (S39). Thus, a second edge-enhanced image is acquired in which image portions of the first end face edge 181 and the second end surface edge 182 in the image (substrate image 152) of the outer peripheral end face 8a of each substrate 8 are enhanced in the same way.

This second edge enhancement processing may include, for example, X-direction differentiation processing on the captured image (grayscale original image), but unlike the above-described first edge-enhanced image (S31), the absolute value of the pixel differential value is required.

In other words, in the second edge-enhanced image, for example, the first end face edge 181, where the pixel differential value exhibits a peak on the positive side and the absolute value of the pixel differential value is relatively large, is represented as a sequence of white pixels with high pixel values (brightness values). Further, for example, the second end face edge 182, where the pixel differential value exhibits a peak on the negative side and the absolute value of the pixel differential value is relatively large, is represented as a sequence of white pixels with high pixel values (brightness values) in the second edge-enhanced image, similar to the first end face edge 181. On the other hand, in the second edge-enhanced image, a region where the absolute value of the pixel differential value is relatively small, such as the outer peripheral end face 8a (particularly the end face region 180) of the substrate 8, where a change in brightness is small, is represented by black pixels with low pixel values (brightness values).

Thus, the first edge-enhanced image is represented in a pixel form that reflects the positive and negative signs of the pixel differential value, whereas the second edge-enhanced image is represented in a pixel form that does not reflect the positive and negative signs of the pixel differential value but reflects the absolute value of the pixel differential value. Therefore, the image portion of the second end face edge 182, represented by black pixels in the above-described first edge-enhanced image, is represented by white pixels in the second edge-enhanced image, similar to the image portion of the first end face edge 181.

Then, image processing is performed to prevent the enhancement of an image region corresponding to the differential background region (S38) in the second edge-enhanced image (S40). The image processing to prevent the enhancement of the image region corresponding to the differential background region as referred to here may involve, for example, replacing pixels of the image region corresponding to the differential background region with black pixels of low pixel values.

As a result of the image processing (S40), the captured image 150 (particularly the captured image 150 with a reduced background image) after the above-described edge enhancement processing (substrate end face enhancement processing; S22 in FIG. 12) is obtained. Therefore, by performing the above-described image processing (particularly the processing after S23 (image sorting processing) in FIG. 12) using the image (captured image 150) obtained as a result of the above-described series of processing (S31 to S40) illustrated in FIG. 16, the plurality of substrates 8 constituting the lot may be detected with high accuracy.

According to the present embodiment as described above, a substrate state monitoring system is provided, which is capable of automatically checking and monitoring whether the substrates 8 are properly held by the substrate support member 36B after liquid processing.

In particular, in the present embodiment, it is checked whether the substrates 8 are properly held by the substrate support member 36B after liquid processing based on a comparison between a captured image of the lot (the plurality of substrates 8) before liquid processing and a captured image of the same lot after liquid processing. In other words, the captured image of the lot before liquid processing is used as a reference image, and data obtained as a result of image processing on the reference image is used as reference information. Then, substrate information obtained as a result of image processing on the captured image of the lot after liquid processing is compared with substrate information before liquid processing, which is reference information, thereby allowing the determination of whether there are any abnormalities in the position, posture, and other conditions of the respective substrates 8 during liquid processing.

Examples of abnormalities include instances where, during liquid processing (batch processing), the substrates 8 unintentionally float in the processing liquid, or the substrates 8 crack. These abnormalities may lead to various process defects, such as the substrate 8 being held in a different slot (e.g., an adjacent slot) from the original slot (substrate holding location) of the substrate support member 36B (jump slot/double). Further, one end of the substrate 8 may be held in the original slot, while the other end of the same substrate 8 is held in the adjacent slot (jump slot/cross).

According to the above-described apparatus and method of the present embodiment, it is possible to automatically and accurately detect such process defects with high reliability, without relying on visual inspection by the user. Furthermore, according to the apparatus and method of the present embodiment, even if the substrate liquid processing system 1A includes a plurality of processing tanks, it is possible to quickly and accurately identify a processing tank where the process defects have occurred, so that the efforts required for recovery work may be reduced and secondary damage may also be effectively prevented.

Further, the position, posture, and other conditions of the plurality of substrates 8 held by the substrate support member 36B will not be exactly the same between lots and may be unique for each lot. For example, in the case of the substrate support member 36B of the present embodiment, where only a portion (e.g., the lower portion) of the plurality of substrates 8 is supported, the other portion (e.g., the upper portion) of the plurality of substrates 8 may shift slightly from the substrate support position.

Therefore, when common reference information, which is registered in advance, is used for detecting (monitoring) abnormalities across multiple lots, it may not always detect process defects of each lot with high accuracy. On the other hand, according to the present embodiment, information obtained from a captured image of each actual processing target lot before liquid processing (particularly immediately before liquid processing) is used as reference information for detecting (monitoring) abnormalities of each lot, so that process defects of each lot may be detected with high accuracy.

Furthermore, according to the present embodiment, the arrangement of the camera 90 and the illuminator 92 for the plurality of substrates 8 serving as an image capturing target is designed in such a way that an image portion of the outer peripheral end face 8a of each substrate 8 in a captured image can be represented as a large-area line-shaped image, rather than as a small-area dot-shaped image. This enables relatively easy and highly accurate acquisition of position information on the outer peripheral end face 8a (and thus position information on the substrate 8) through image processing of the captured image.

In particular, in the present embodiment, the image portion of the outer peripheral end face 8a of each substrate 8 in the captured image is sufficiently larger than an image portion of the notch N, so that the effect of the notch N on the detection accuracy of process defects may be suppressed.

It is to be noted that the embodiments and modifications disclosed in this specification are merely illustrative in all respects and should not be interpreted in a limiting way. The above-described embodiments and modifications may be omitted, substituted, and modified in various forms without departing from the scope and spirit of the appended claims. For example, the above-described embodiments and modifications may be combined either in whole or in part, and embodiments other than those described above may be combined with the above-described embodiments or modifications. In addition, the effects described in this specification are merely illustrative, and other effects may be achieved.

The technical categories embodying the above-described technical ideas are not limited. For example, the above-described technical ideas may be embodied by a computer program that causes a computer to execute one or more procedures (steps) included in a method of manufacturing or using the above-described apparatus. Further, the above-described technical ideas may also be embodied by a computer readable non-transitory recording medium on which the computer program is recorded.

According to the present disclosure, it is possible to provide a technique that is advantageous for checking whether a substrate after immersion in a processing liquid is properly held by a substrate holding member.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate liquid processing apparatus comprising:
a processing tank configured to store a processing liquid;
a substrate support member configured to support a plurality of substrates in an upright posture with an interval therebetween;
a support mover configured to move the substrate support member, so as to arrange the plurality of substrates at a processing position where the plurality of substrates are positioned within the processing tank so as to be immersed in the processing liquid and at a retreat position where the plurality of substrates are positioned outside the processing tank;
an image capturer configured to acquire a captured image of outer peripheral end faces of the plurality of substrates; and
an image processor configured to make a determination on a positional misalignment between the plurality of substrates before immersion in the processing liquid and the plurality of substrates after immersion in the processing liquid, based on a comparison between the captured image of the outer peripheral end faces of the plurality of substrates before immersion in the processing liquid and the captured image of the outer peripheral end faces of the plurality of substrates after immersion in the processing liquid.

2. The substrate liquid processing apparatus of claim 1, further comprising an illuminator configured to emit light,
wherein the image capturer acquires the captured image of the outer peripheral end faces of the plurality of substrates illuminated by the light emitted from the illuminator located between the image capturer and the outer peripheral end faces of the plurality of substrates.

3. The substrate liquid processing apparatus of claim 1, further comprising an illuminator including a plurality of point light sources arranged in a line,
wherein the image capturer acquires the captured image of the outer peripheral end faces of the plurality of substrates illuminated by light emitted from the plurality of point light sources.

4. The substrate liquid processing apparatus of claim 1, wherein an image portion of the outer peripheral end faces of the plurality of substrates in the captured image includes a plurality of interconnected light spot images.

5. The substrate liquid processing apparatus of claim 1, wherein the plurality of substrates are supported by the substrate support member so as to be upright in a first direction, and an image capturing direction of the image capturer when acquiring the captured image is inclined relative to the first direction.

6. The substrate liquid processing apparatus of claim 2, wherein the plurality of substrates are supported by the substrate support member so as to be upright in a first direction, and
wherein, when the image capturer captures an image of the outer peripheral end faces of the plurality of substrates, the illuminator emits light to the outer peripheral end faces of the plurality of substrates in a direction that is inclined relative to the first direction.

7. The substrate liquid processing apparatus of claim 1, wherein the image capturer acquires the captured image in a state where the plurality of substrates, supported by the substrate support member, are positioned outside the processing tank.

8. The substrate liquid processing apparatus of claim 1, wherein each of the plurality of substrates has a notch on an outer periphery thereof, and
wherein the captured image includes an image of the outer peripheral end face that has a range greater than twice a range of the notch on the outer periphery of each of the plurality of substrates.

9. The substrate liquid processing apparatus of claim 1, wherein the image processor is configured to:
determine a substrate image region including at least a part of an image portion of the outer peripheral end faces of the plurality of substrates in the captured image; and
make the determination based on a comparison between the substrate image region in the captured image of the outer peripheral end faces of the plurality of substrates before immersion in the processing liquid and the substrate image region in the captured image of the outer peripheral end faces of the plurality of substrates after immersion in the processing liquid.

10. The substrate liquid processing apparatus of claim 1, wherein the image processor is configured to:
determine a substrate image region including at least a part of an image portion of the outer peripheral end faces of the plurality of substrates in the captured image;
perform edge enhancement processing on the substrate image region;
perform pixel sorting processing to rearrange pixels included in image data of the substrate image region after the edge enhancement processing; and
make the determination based on a comparison between image data of the substrate image region after the pixel sorting processing on the captured image of the outer peripheral end faces of the plurality of substrates before immersion in the processing liquid and image data of the substrate image region after the pixel sorting processing on the captured image of the outer peripheral end faces of the plurality of substrates after immersion in the processing liquid,
wherein the image data to be subjected to the pixel sorting processing includes a plurality of pixel sets arranged in a direction perpendicular to a substrate image extension direction in which an image portion of each of the plurality of substrates extends, and
wherein the pixel sorting processing rearranges a plurality of pixels included in each of the plurality of pixel sets and arranged in the substrate image extension direction, according to a magnitude of a brightness value.

11. A substrate liquid processing method comprising:
acquiring a captured image of outer peripheral end faces of a plurality of substrates, supported by a substrate support member in an upright posture with an interval therebetween, before immersion in a processing liquid within a processing tank;
positioning the plurality of substrates, supported by the substrate support member, within the processing tank so as to be immersed in the processing liquid within the processing tank;
acquiring a captured image of the outer peripheral end faces of the plurality of substrates, supported by the substrate support member, after immersion in the processing liquid within the processing tank; and
making a determination on a positional misalignment between the plurality of substrates before immersion in the processing liquid and the plurality of substrates after immersion in the processing liquid, based on a comparison between the captured image of the outer peripheral end faces of the plurality of substrates before immersion in the processing liquid and the captured image of the outer peripheral end faces of the plurality of substrates after immersion in the processing liquid.

12. An image processing method comprising:
acquiring a captured image of outer peripheral end faces of a plurality of substrates, supported by a substrate support member in an upright posture with an interval therebetween, before immersion in a processing liquid within a processing tank;
acquiring a captured image of the outer peripheral end faces of the plurality of substrates, supported by the substrate support member in the upright posture with the interval therebetween, after immersion in the processing liquid within the processing tank; and
making a determination on a positional misalignment between the plurality of substrates before immersion in the processing liquid and the plurality of substrates after immersion in the processing liquid, based on a comparison between the captured image of the outer peripheral end faces of the plurality of substrates before immersion in the processing liquid and the captured image of the outer peripheral end faces of the plurality of substrates after immersion in the processing liquid.
